(19) United States
(12) Patent Application Publication
(10) Pub. No.: US 2015/0097317 A1
(43) Pub. Date: Apr. 9, 2015

(54) METHOD OF FABRICATING MAGNETICALLY ACTUATED ARTIFICIAL CILIA

(71) Applicant: National Taiwan University of Science and Technology, Taipei (TW)

(72) Inventors: Chia-Yuan Chen, New Taipei City (TW); Cheng-Yi Lin, Taichung City (TW)

(73) Assignee: National Taiwan University of Science and Technology, Taipei (TW)

(21) Appl. No.: 14/093,536

(22) Filed: Dec. 2, 2013

(30) Foreign Application Priority Data
Oct. 9, 2013 (TW) 102136574

(51) Int. Cl. H01F 41/02; B81C 99/00; B29C 67/24

(52) U.S. Cl. CPC H01F 41/0266; B29C 67/24; B81C 99/0075
USPC 264/429; 264/319; 264/101

(57) ABSTRACT

Provided is a method of fabricating magnetic cilia including the following steps. Step (A): A mold is provided in which a plurality of micro-channels are formed, wherein the aperture of each of the micro-channels is between 50 μm and 350 μm, and the depth of each of the micro-channels is between 500 μm and 3,500 μm. Step (B): A raw material is spread onto the mold and filled into each of the micro-channels, wherein the raw material includes a polymer and magnetic particles dispersed therein. Step (C): A heat treatment is performed to harden the raw material in each of the micro-channels into a magnetic cilium. Step (D): A mold release process is performed to isolate each of the magnetic cilia from each of the micro-channels.

### CROSS-REFERENCE TO RELATED APPLICATION

This application claims the priority benefit of Taiwan application serial no. 102136574, filed on Oct. 9, 2013. The entirety of the above-mentioned patent application is hereby incorporated by reference herein and made a part of this specification.

### BACKGROUND OF THE INVENTION

1. Field of the Invention

The invention relates to a method of fabricating cilia, and more particularly, to a method of fabricating magnetically actuated artificial cilia capable of being driven by a magnetic force.

2. Description of Related Art

Microfluidics or lab on a chip is a technique developed from the concept that the processes of preparing, reacting, separating, and testing a sample are all performed on the same chip. Traditional time-consuming and laborious bio-analysis has been improved significantly in terms of quality and quantity by the development of the technique.

One of the major functionalities of microfluidics or lab on a chip is the rapid and complete mixing of biological samples. The functionality can be achieved by changing the geometric design of micro-channels. In this regard, designs of, for instance, herringbone channels, serpentine channels, and spiral channels have been proposed. However, changing only the design of the channels is a passive method of mixing, and the disadvantage thereof is that the length needed for the channels is generally too long. Moreover, fluids with higher viscosity cannot be mixed efficiently. Therefore, a more plausible method may be to dispose an active micromixer in the channels and to operate the micromixer through an external force. For instance, an external force based on light, electricity, magnetism, or heat can be applied to the micromixer so as to perform a non-reciprocating motion in the channels in a certain mode so as to generate a specific flow field and facilitate micromixing.

### SUMMARY OF THE INVENTION

The invention provides a method of fabricating magnetically actuated artificial cilia. The method can easily and rapidly produce magnetically actuated artificial cilia.

The method of fabricating magnetically actuated artificial cilia of the invention includes the following steps.
Step (A): A mold is provided in which a plurality of micro-channels are formed, wherein the aperture of each of the micro-channels is between 50 μm and 350 μm, and the depth of each of the micro-channels is between 500 μm and 3,500 μm.
Step (B): A raw material is spread onto the mold and filled into each of the micro-channels, wherein the raw material includes a polymer and magnetic particles dispersed therein.
Step (C): A heat treatment is performed to harden the raw material in each of the micro-channels into a magnetic cilium.
Step (D): A mold release process is performed to isolate each of the magnetic cilia from each of the micro-channels.

In an embodiment of the invention, when performing step (B), the mold with the raw material spread thereon is evacuated.

In an embodiment of the invention, when performing step (B), a magnetic field is applied to the mold with the raw material spread thereon, wherein the direction of the magnetic field is parallel to the extending direction of the micro-channels.

In an embodiment of the invention, the method of fabricating magnetically actuated artificial cilia further includes, after step (B) and before step (C), a step (E): The raw material located on the mold and outside of each of the micro-channels is removed.

In an embodiment of the invention, step (B) and step (E) are performed repeatedly.

In an embodiment of the invention, the method of fabricating magnetically actuated artificial cilia further includes, after step (E) and before step (C), a step (F): A supporting layer is formed on the mold, wherein the supporting layer is combined with each of the magnetically actuated artificial cilia after step (C).

In an embodiment of the invention, the polymer includes poly dimethyl siloxane (PDMS).

In an embodiment of the invention, the magnetic particles include NdFeB.

In an embodiment of the invention, the weight ratio of the magnetic particles to the polymer in the raw material is 1/1 to 100/1, for example, 1/1 to 5/1.

In an embodiment of the invention, the micro-channels are formed by a micro-machining or a micro-milling method.

Based on the above, the invention provides a method of fabricating magnetically actuated artificial cilia. The method is simpler and faster compared to known methods. Furthermore, the cost required is low and the success rate of the mold release process is high. By using the method of the invention, the electromagnetic and mechanical properties of the magnetically actuated artificial cilia can also be adjusted by varying the amount of the magnetic particles or the polymer. Therefore, the method of the invention is suitable for use in microfluidic experiments.

To make the above features and advantages of the invention more comprehensible, several embodiments are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are flow charts of a method of fabricating magnetically actuated artificial cilia illustrated according to the first embodiment of the invention.

FIG. 2 is a partial schematic view of a micro-channel having magnetically actuated artificial cilia.

FIG. 3A and FIG. 3B are scanning electronic microscope (SEM) micrographs of magnetically actuated artificial cilia obtained from an experiment.

### DESCRIPTION OF THE EMBODIMENTS

In the present text, ranges represented by “a numerical value to another numerical value” are shorthand representations used to avoid listing all of the numerical values in the specification. Therefore, the recitation of a specific numerical range is equivalent to the recitation of any numerical value in the numerical range and a smaller numerical range defined by any numerical value in the numerical range, as is the case with said numerical value and said numerical range being disclosed in the specification. For instance, recitation of “a depth of 10 to 300 μm” discloses a range of “a depth of 100 to 250 μm” regardless of whether other numerical values were cited in the specification.

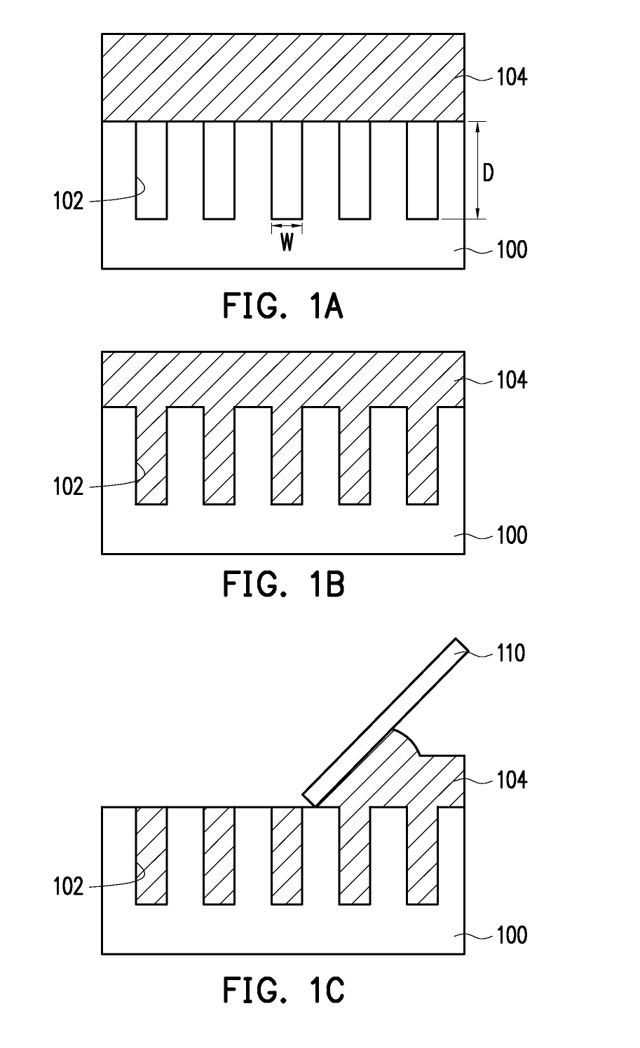

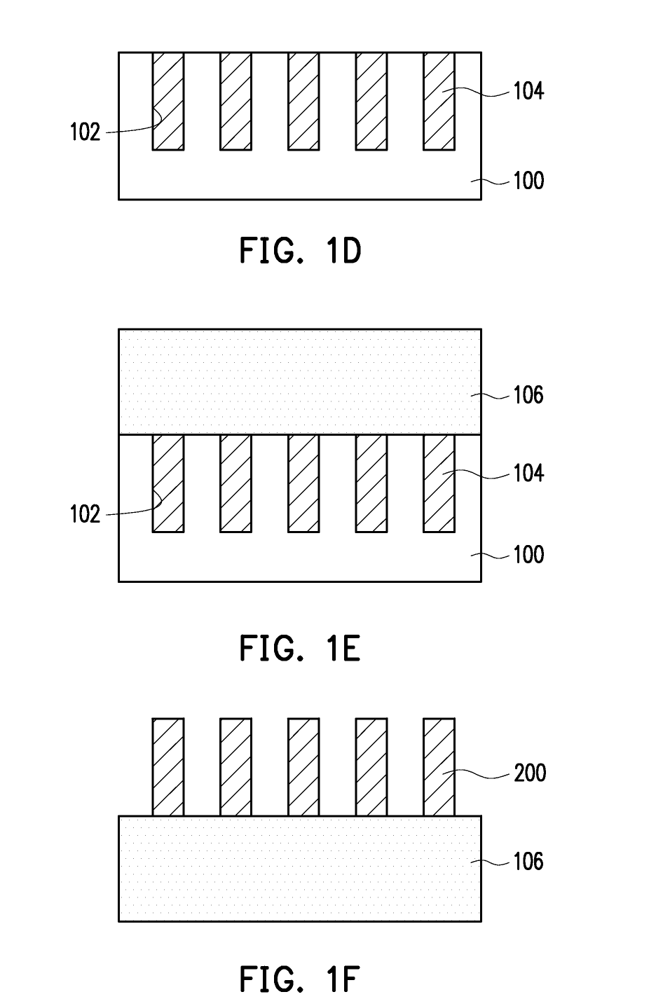

The first embodiment of the invention is related to a method of fabricating magnetically actuated artificial cilia. The method is described in the following with reference to FIG. 1A to FIG. 1F. The series of figures illustrate flow charts of fabricating magnetically actuated artificial cilia.

In the present embodiment, the method of fabricating magnetically actuated artificial cilia includes the following steps.

Referring to FIG. 1A, a mold 100 is first provided. A plurality of micro-channels 102 are preformed in the mold 100. In particular, an aperture W of each of the micro-channels 102 is between 50 μm and 350 μm, a depth D of each of the micro-channels 102 is between 500 μm and 3,500 μm, and an aspect ratio (D/W) of each of the micro-channels 102 is between 1 and 10. Each of the magnetically actuated artificial cilia fabricated using the mold 100 has a length, a width, and an aspect ratio corresponding to each of the micro-channels 102. In particular, a high aspect ratio indicates the magnetically actuated artificial cilia can oscillate at a greater amplitude when driven by an external force. The particular characteristic is beneficial for applications related to microfluidics.

The mold 100 can be an acrylic material, and each of the micro-channels 102 can be formed on the mold 100 by using a micro-machining or a micro-milling process. Of course, the invention is not limited thereto. In other embodiments, other known methods such as a lithography process can also be used to form each of the micro-channels. However, considering the aspects in the following, a micro-machining or a micro-milling process may be more competitive than a lithography process.

First, if a lithography method is used to form a mold, the aspect ratio thereof cannot be too high, for example, cannot be greater than 5:1. Further, if a high aspect ratio is desired, since the photoresist cannot be stacked to such height in one attempt, it needs to be coated layer by layer, and the uniformity of the photoresist coated on the mold at a high aspect ratio is very poor in that the difference in thickness on each of the left and right sides can be hundreds of microns or more. The poor uniformity of the photoresist has a very negative impact on the size uniformity of the magnetically actuated artificial cilia. The micro-milling method does not have the issues above, and even an aspect ratio of greater than 10:1 does not pose a risk. As described above, the micro-milling method has a very positive effect on the amplitude of oscillation of each of the magnetically actuated artificial cilia since a greater aspect ratio results in a greater amplitude of oscillation. As a result, a greater flow disturbance can be generated to facilitate micromixing.

Moreover, if a lithography process is used, a photoresist can only be coated from above the wafer. In other words, the resulting pattern can only be distributed in two dimensions. However, micro-milling can be performed from any direction, and therefore the resulting cilia can extend toward different directions. If a five-axis processing machine is used, then cilia having a smooth surface or other geometric shapes can be made, thus broadening the application scope of the cilia.

The shape of each of the micro-channels 102, that is, the shape of each of the micro-channels 102 seen when observing the mold 100 from the top down, is generally not particularly limited. In the present embodiment, the shape can be a circle. Alternately, the shape can be a regular polygon, an ellipse, or other regular or irregular shapes.

Referring further to FIG. 1A, next, a raw material 104 is spread onto the mold 100. The raw material 104 is a fluid at this step, and any known coating method can be used to spread the raw material 104 onto the mold 100. For instance, the raw material 104 can be directly poured onto the mold 100. The raw material 104 includes a polymer and magnetic particles, and in the first embodiment, the polymer and the magnetic particles can respectively be polydimethyl siloxane (PDMS) and NdFeB particles. However, the invention is not limited thereto. In other embodiments, the polymer can also be agarose or hydrogel, and the magnetic particles can also include Fe₃O₄, Alnico, iron, cobalt, nickel, or any known magnetic material. Moreover, the particle size of each of the magnetic particles is, for instance, between 1 μm and 10 μm. If the polymer contains PDMS, then a hardener such as Sylgard 184B produced by Dow Corning can further be contained in the raw material 104.

Moreover, in the raw material 104, the relative amount of each of the polymer and the magnetic particles can be adjusted to achieve the predetermined electromagnetic and mechanical properties. Of course, if the amount of the polymer is too small, then the mechanical properties of the magnetically actuated artificial cilia may be poor, and if the amount of the magnetic particles is too small, then the magnetic properties of the magnetically actuated artificial cilia may be weaker such that a stronger magnetic force is needed to control the magnetically actuated artificial cilia. Therefore, in the present embodiment, the weight ratio of the magnetic particles to the polymer in the raw material 104 is 1/1 to 5/1, preferably 2/1 to 3/1.

Since the raw material 104 is a fluid, after being spread onto the mold 100, the raw material 104 slowly flows into each of the micro-channels 102. However, if the viscosity of the raw material 104 is too high, then it may be difficult to completely fill the raw material 104 into each of the micro-channels 102. In this case, a number of methods can be used to assist in filling the raw material 104 into each of the micro-channels 102. For instance, the mold 100 with the raw material 104 spread thereon can be evacuated to extract air originally sealed inside each of the micro-channels 102 such that the raw material 104 can be filled into each of the micro-channels 102 more thoroughly. Alternately, a filament having a size slightly smaller than each of the micro-channels 102 can also be used to physically insert the raw material 104 into each of the micro-channels 102 with an external force. Alternately, a magnetic field can also be applied to the mold 100 with the raw material 104 spread thereon. In particular, the direction of the magnetic field is, for instance, substantially parallel to the extending direction (i.e., the depth direction) of the micro-channels 102. Applying a magnetic field not only helps the raw material 104 containing magnetic particles to move along the depth direction of each of the micro-channels 102, but can also help the rearrangement and reorganization of magnetic particles dispersed in the polymer. Lastly, with the desired state shown in FIG. 1B, the raw material 104 is completely filled into each of the micro-channels 102.

In the state illustrated in FIG. 1B, if the raw material 104 located in each of the micro-channels 102 is hardened, then the raw material 104 in each of the micro-channels 102 is formed into a magnetically actuated artificial cilium. The method of hardening is not particularly limited. For instance, if the raw material 104 contains PDMS and a hardener, then a heat treatment can be performed on the mold 100 to facilitate the hardening process.

In the present embodiment, other steps may be performed before the heat treatment, and the details of the steps are as described below.

Referring to FIG. 1C, the raw material 104 located outside of each of the micro-channels 102 on the mold 100 is removed. The method of removal includes, for instance, scrapping the raw material 104 located outside of each of the micro-channels 102 on the mold 100 with a scraper 110. If the present step is not performed, then a layer of the raw material 104 would remain on the surface of the mold 100. This thin layer would exist after the hardening process and the mold release process. As a result, a plurality of magnetically actuated artificial cilia would stand on a layer of magnetic thin film after the mold release process. Although the properties of the magnetically actuated artificial cilia are not affected thereby, an effect of magnetic shielding may be generated such that the magnetically actuated artificial cilia are difficult to control.

Referring to FIG. 1D, the steps illustrated in FIG. 1A, FIG. 1B, and FIG. 1C can be performed repeatedly. Specifically, the steps of spreading the raw material 104 onto the mold 100, filling the raw material 104 into each of the micro-channels 102 (this step can include evacuation, applying a magnetic field, or physically applying pressure as needed), and removing (e.g., scraping) the raw material 104 on the mold 100 are performed repeatedly. By repeatedly performing the steps, the raw material 104 can be more thoroughly and densely filled into each of the micro-channels 102.

Referring to FIG. 1E, next, a supporting layer 106 is formed on the mold 100. The supporting layer 106 can contain a polymer. For instance, the supporting layer 106 in the present embodiment can contain PDMS. The supporting layer 106 and the raw material 104 containing the same polymer may be beneficial for the bonding strength between the two. Of course, the invention is also not limited thereto. The material of the supporting layer 106 can also be different from the polymer contained in the raw material 104.

Then, a heat treatment is performed on the mold 100, the raw material 104, and the supporting layer 106 to harden the raw material 104 in each of the micro-channels 102 into a magnetically actuated artificial cilium 200 and to combine each of the magnetically actuated artificial cilia 200 with the supporting layer 106.

Referring to FIG. 1F, next, a mold release process is performed to isolate each of the magnetically actuated artificial cilia 200 from each of the micro-channels 102. The mold release process is not particularly limited, and can include, for instance, manually separating each of the magnetically actuated artificial cilia 200 from each of the micro-channels 102 to complete the fabrication of the magnetically actuated artificial cilia 200.

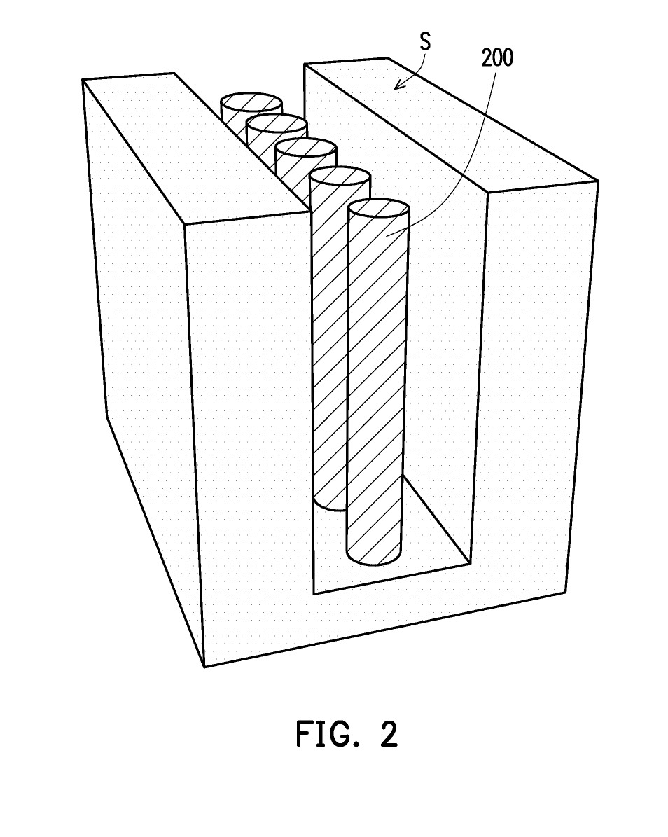

It should be mentioned here that, in the present embodiment, FIG. 1F only illustrates a cross-sectional diagram of a partial area of a product after the mold release process. The overall product may be as shown in FIG. 2. In particular, the parts other than the magnetically actuated artificial cilia 200 are all made of the same material. For the product illustrated in FIG. 2, if the parts other than the magnetically actuated artificial cilia 200 are all made of PDMS, then an oxygen plasma process can be performed on a surface S thereof such that the surface S becomes hydrophilic. Afterward, a hot pressing method is used to press fit a glass substrate 112 onto the surface S to form a sealed channel. Then, the micro-channel structure can be used to study the behavior of microfluidics. In particular, each of the magnetically actuated artificial cilia 200 can be driven by applying a magnetic field. For instance, a magnetic coil can be set up around the micro-channels and a driving circuit can be designed to drive the magnetically actuated artificial cilia 200. Applying a magnetic field using different methods can cause an array of magnetically actuated artificial cilia to generate different movement patterns. Accordingly, the behavior mode of microfluidics, such as different mixing modes of two fluids, can be studied under various three-dimensional flow fields.

### Experiment

To demonstrate the feasibility of the invention, the following experimental example is cited to describe the invention more specifically. Although the following experiment is described, the materials used and the amount and ratio of the materials, as well as handling details and handling process . . . etc., can be modified without exceeding the scope of the invention. Accordingly, restrictive interpretation should not be made to the invention based on the experiment described below.

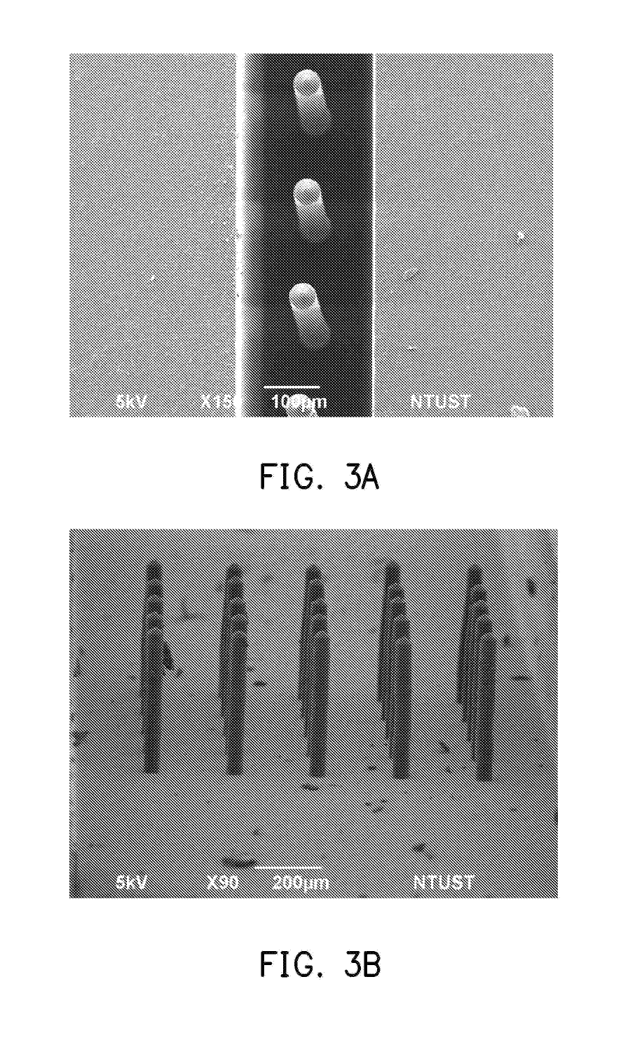

Magnetically actuated artificial cilia were fabricated according to the process shown in FIG. 1A to FIG. 1F. The polymer used in the experiment is PDMS (Sylgard 184A, manufacturer: Dow Corning, agent: SILMORE), the hardener thereof is Sylgard 184B, manufacturer: Dow Corning, agent: SILMORE, and the magnetic particles are NdFeB particles (neodymium-iron-boron, Magnequench, Singapore) having a particle size of 5 μm. The NdFeB particles were mixed into the PDMS in a weight ratio of 3:1 to make a PDMS/NdFeB mixture. The PDMS/NdFeB mixture was spread onto an acrylate mold. In particular, an array of micro-channels each having a diameter of 50 μm and a depth of 300 μm was preformed on the acrylate mold with a micro-milling machine (VCY Co., Ltd., customized assembly model). The acrylate mold was placed in a chamber, and a mechanical pump (UN-90V, manufacturer: Uni-Crown) was used to evacuate the chamber to a low vacuum (about 10⁻¹ torr) state to remove air filled in the microchannel initially (a higher vacuum state is possible if necessary) such that the PDMS/NdFeB mixture was able to be filled into each of the micro-channels completely to form a prototype of magnetically actuated artificial cilia. After excess material was scraped from the surface of the acrylate mold, the entire mold was completely filled with transparent PDMS. After soft baking and curing at a low temperature (about 80° C.) for 2 hours, a mold release process was performed to obtain the magnetically actuated artificial cilia. The SEM micrographs of two fabricated products are as shown in FIG. 3A and FIG. 3B.

FIG. 3A shows a top view SEM micrograph of a micro-channel product. In particular, a row of magnetically actuated artificial cilia containing PDMS and NdFeB is disposed in the micro-channel, and the material of the sidewall is PDMS. FIG. 3B shows a 5×5 array of magnetically actuated artificial cilia.

By observing FIG. 3A and FIG. 3B, it can be seen that the structure of each of the magnetically actuated artificial cilia is intact with no visible defects or faults. Moreover, the top of each of the magnetically actuated artificial cilia appears conical, faithfully reflecting the bottom configuration of micro-channels fabricated with a micro-milling machine. All of the above can prove that the filling effect of the PDMS/NdFeB mixture is in an optimized manner.

Based on the above, the invention provides a method of fabricating magnetically actuated artificial cilia. The method is simpler and faster compared to known methods. Moreover, the cost required is low and the success rate of the mold release process is high. By using the method of the invention, the electromagnetic and mechanical properties of the cilia can also be adjusted by varying the amount of the magnetic particles, the polymer, or the hardener. Therefore, the method of the invention is suitable for use in microfluidic experiments.

Although the invention has been described with reference to the above embodiments, the invention is not limited thereto. It will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. A method of fabricating magnetically actuated artificial cilia, comprising:
(A) providing a mold in which a plurality of micro-channels are formed, wherein an aperture of each of the micro-channels is between 50 μm and 350 μm, and a depth of each of the micro-channels is between 500 μm and 3,500 μm;
(B) spreading a raw material onto the mold and filling the raw material into each of the micro-channels, wherein the raw material comprises a polymer and magnetic particles dispersed therein;
(C) performing a heat treatment to harden the raw material in each of the micro-channels into a magnetic cilium; and
(D) performing a mold release process to isolate each of the magnetic cilia from each of the micro-channels.

2. The method of claim 1, wherein when performing step (B), the mold with the raw material spread thereon is evacuated.

3. The method of claim 2, wherein when performing step (B), a magnetic field is applied to the mold with the raw material spread thereon, and a direction of the magnetic field is substantially parallel to an extending direction of the micro-channels.

4. The method of claim 3, further comprising, after step (B) and before step (C), (E) removing the raw material located on the mold and outside of each of the micro-channels.

5. The method of claim 4, wherein step (B) and step (E) are performed repeatedly.

6. The method of claim 4, further comprising, after step (E) and before step (C), (F) forming a supporting layer on the mold, wherein the supporting layer is combined with each of the magnetically actuated artificial cilia after step (C).

7. The method of claim 1, wherein the polymer comprises poly dimethyl siloxane (PDMS).

8. The method of claim 1, wherein the magnetic particles comprise NdFeB.

9. The method of claim 1, wherein in the raw material, a weight ratio of the magnetic particles to the polymer is 1/1 to 5/1.

10. The method of claim 1, wherein the micro-channels are formed by a micro-machining or a micro-milling method.
